(19) United States
(12) Patent Application Publication
(10) Pub. No.: US 2014/0023794 A1
(43) Pub. Date: Jan. 23, 2014

(54) Method And Apparatus For Low Temperature ALD Deposition

(71) Applicants: Maitreyee Mahajani, Saratoga, CA (US); Steven D. Marcus, San Jose, CA (US); Li-Qun Xia, Cupertino, CA (US); Mihaela Balseanu, Sunnyvale, CA (US); Victor Nguyen, Novato, CA (US); Ning Li, San Jose, CA (US); Jingjing Liu, Sunnyvale, CA (US); Sukti Chatterjee, Cupertino, CA (US); Timothy W. Weidman, Sunnyvale, CA (US)

(72) Inventors: Maitreyee Mahajani, Saratoga, CA (US); Steven D. Marcus, San Jose, CA (US); Li-Qun Xia, Cupertino, CA (US); Mihaela Balseanu, Sunnyvale, CA (US); Victor Nguyen, Novato, CA (US); Ning Li, San Jose, CA (US); Jingjing Liu, Sunnyvale, CA (US); Sukti Chatterjee, Cupertino, CA (US); Timothy W. Weidman, Sunnyvale, CA (US)

(21) Appl. No.: 13/948,492

(22) Filed: Jul. 23, 2013

Related U.S. Application Data
(60) Provisional application No. 61/674,631, filed on Jul. 23, 2012.
(60) Provisional application No. 61/789,579, filed on Mar. 15, 2013.

(51) Int. Cl. C23C 16/32; C23C 16/36; C23C 16/34

(52) U.S. Cl. CPC C23C 16/325; C23C 16/345; C23C 16/36
USPC 427/535

(57) ABSTRACT

Provided are methods and apparatus for low temperature atomic layer deposition of a densified film. A low temperature film is formed and densified by exposure to one or more of a plasma or radical species. The resulting densified film has superior properties to low temperature films formed without densification.

### CROSS-REFERENCE TO RELATED APPLICATIONS

This application claims priority to U.S. Provisional Application No. 61/674,631, filed Jul. 23, 2012, and U.S. Provisional Application No. 61/789,579, filed Mar. 15, 2013.

### BACKGROUND

Embodiments of the invention generally relate to an apparatus and methods for depositing silicon nitride, silicon carbide and silicon carbonitride films on a substrate. More specifically, embodiments of the invention are directed to atomic layer deposition chambers and methods of depositing low temperature silicon nitride silicon carbide and silicon carbonitride films with improved film quality.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a region of a substrate (or all of the substrate) is contacted with a first reactant which is adsorbed onto the substrate surface. The substrate is then contacted with a second reactant which reacts with the first reactant to form a deposited material. A purge gas may be introduced between the delivery of each reactant gas to ensure that the only reactions that occur are on the substrate surface.

Atomic layer deposition has been widely used for the deposition of dielectrics, high-k dielectrics and metal liners. With the thermal budget of the resulting device in mind, low temperature depositions are preferred. However, low temperature deposition of many materials, including silicon nitride, result in films with poor performance characteristics. Therefore, there is an ongoing need in the art for low temperature methods of depositing films with good performance characteristics.

### SUMMARY

One or more embodiments of the invention are directed to methods of forming a film on a substrate in a processing chamber. The methods comprise sequentially exposing the substrate to a first reactive gas comprising silicon and a second reactive gas comprising one or more of a reducing agent and an oxidizing agent to form a film. The film being one or more of silicon nitride, silicon carbide and silicon carbonitride. The film is densified with a densifying gas comprising one or more of a plasma and radicals to form a densified film. The film is formed at a temperature less than about 500° C.

In some embodiments, the first reactive gas is a silicon halide. In one or more embodiments, the second reactive gas comprises one or more of ammonia and hydrazine.

In some embodiments, the densifying gas is one or more of argon, nitrogen, hydrogen, helium, ammonia nitric oxide and nitrous oxide. In one or more embodiments, the densifying gas is the second reactive gas and the densified film is formed at substantially the same time as the film. In some embodiments, the film is densified without being exposed to ambient conditions.

In one or more embodiments, the densifying gas is a third gas different from the first reactive gas and the second reactive gas, and the film is exposed to a plasma of the third gas. In some embodiments, exposure to the plasma occurs at a temperature of less than about 50° C. In one or more embodiments, the plasma is formed remotely from the processing chamber. In some embodiments, the plasma is formed within the processing chamber.

In some embodiments, the densifying gas is a third gas different from the first reactive gas and the second reactive gas. The film is exposed to radicals of the third gas. The radicals being generated by passing the third gas across a thermal element.

In some embodiments, the film is densified after each exposure to the first reactive gas and the second reactive gas. In one or more embodiments, the film is densified after forming a film having a thickness in the range of about 1 Å to about 50 Å.

In some embodiments, the densified film has a wet etch rate less than about 150 Å/minute. In one or more embodiments, the densified film has a leakage current less than about 1×10⁹ Å/cm². In some embodiments, the densified film has a breakdown voltage greater than about 8 MV.

In some embodiments, exposure to the first reactive gas and the second reactive gas occur substantially simultaneously at different regions of the substrate. In one or more embodiments, exposure to the first reactive gas and the second reactive gas occur separately, each across the entire substrate.

Additional embodiments of the invention are directed to methods of forming a densified film comprising one or more of silicon nitride, silicon carbide or silicon carbonitride. The substrate is sequentially exposed to a first reactive gas comprising silicon and a second reactive gas comprising an agent to form a film on a surface of the substrate. The being formed at a temperature less than about 500 ° C. and comprising one or more of silicon nitride, silicon carbide and silicon carbonitride. The film is exposed to a plasma a third gas to form a densified film, the third gas selected from the group consisting of Ar, N₂, H₂, He, NH₃ and mixtures thereof.

Further embodiments of the invention are directed to methods of forming a densified silicon nitride film. A substrate is sequentially exposed to a first reactive gas comprising silicon and a second reactive gas comprising a reducing agent to form a silicon nitride film on a surface of the substrate. The silicon nitride film is formed at a temperature less than about 500° C. The silicon nitride film is exposed to one or more of a plasma of a third gas or radicals of a third gas to form a densified silicon nitride film. The radicals formed by passing the third gas across a thermal element. The third gas selected from the group consisting of Ar, N₂, H₂, He, NH₃ and mixtures thereof.

Additional embodiments of the invention are directed to methods of forming a film on a substrate. The substrate is sequentially exposed to a first reactive gas comprising dichlorosilane or hexachlorodisilane and a second reactive gas comprising ammonia to form a film. The film is densified with a densifying gas comprising one or more of a plasma and radicals to form a densified film and/or exposing the film to heat from a hot wire. The film being formed at a temperature less than about 500° C.

In some embodiments, the densifying gas comprises one or more of a plasma and raidcals to form the densified film. In one or more embodiments, the plasma comprises Ar and N₂. In some embodiments, the densifying gas contains N* radicals. In one or more embodiments, exposing the densifying gas to heat from a hot wire produces N* and/or NH* radicals.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional view of an atomic layer deposition chamber according to one or more embodiments of the invention;

FIG. 2 shows a susceptor in accordance with one or more embodiments of the invention;

FIG. 3 shows a schematic view of a processing chamber with a gas distribution plate and a thermal element in accordance with one or more embodiments of the invention;

FIG. 4 shows a partial cross-sectional side view of an atomic layer deposition chamber in accordance with one or more embodiments of the invention;

FIG. 5 shows a partial cross-sectional side view of an atomic layer deposition chamber in accordance with one or more embodiments of the invention;

FIG. 6 shows a partial cross-sectional side view of an atomic layer deposition chamber in accordance with one or more embodiments of the invention; and

FIG. 7 shows a partial cross-sectional side view of an atomic layer deposition chamber in accordance with one or more embodiments of the invention;

FIG. 8 shows a partial cross-sectional side view of an atomic layer deposition chamber in accordance with one or more embodiments of the invention;

FIG. 9 shows a partial cross-sectional side view of the lid assembly from FIG. 8;

FIG. 10 shows a partial cross-sectional side view of the support assembly from FIG. 8;

FIG. 11 shows a schematic view of a deposition system in accordance with one or more embodiment of the invention; and

FIG. 12 shows a schematic view of a cluster tool in accordance with one or more embodiments of the invention.

### DETAILED DESCRIPTION

Embodiments of the invention are directed to atomic layer deposition apparatus and methods for depositing a film. For example, a silicon nitride, silicon carbide and/or silicon carbonitride film can be deposited. One or more embodiments of the invention are directed to atomic layer deposition apparatuses (also called cyclical deposition) suitable for the deposition of silicon nitride, silicon carbide and/or silicon carbonitride (or other) films.

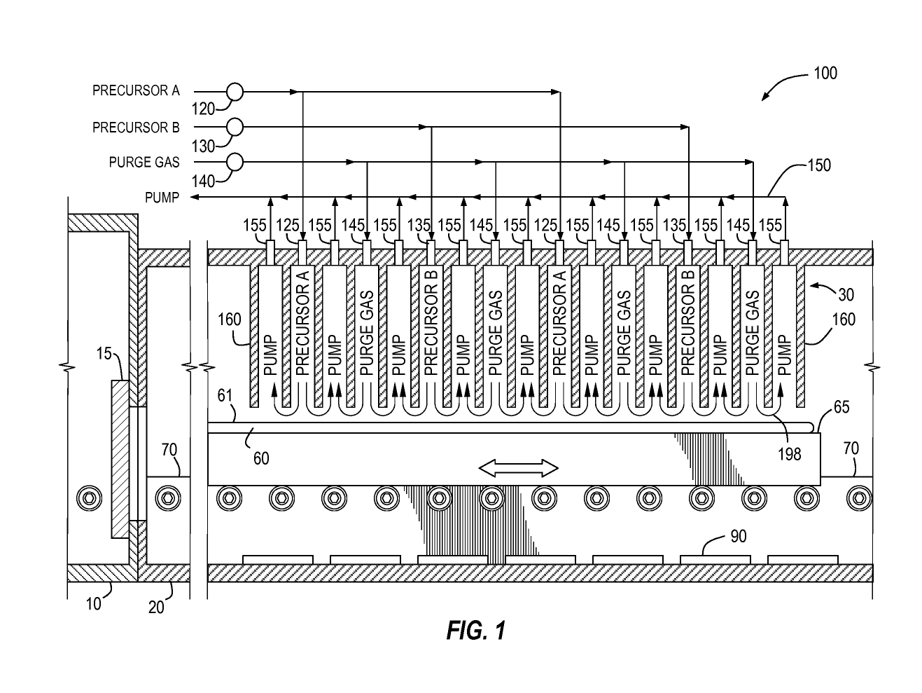

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited thereon.

As used in this specification and the appended claims, the term “reactive gas” is used interchangeably with “precursor” and means a gas that includes a species which is reactive in an atomic layer deposition process. For example, a first “reactive gas” may simply adsorb onto the surface of a substrate and be available for further chemical reaction with a second reactive gas.

ALD silicon nitride can be deposited by halide and ammonia chemistry over a wide temperature range (e.g., <200° C. to 700° C.). However, the quality of the SiN degrades for deposition temperatures less than about 500° C. Embodiments of the invention are directed to methods and process sequences to deposit silicon nitride, silicon carbide and silicon carbonitride films at lower temperatures and perform post processing to improve the film quality. Thermal ALD deposition using halide chemistry and a reductant (or oxidant) followed by plasma treatment of the film to improve quality. As will be understood by those skilled in the art, a plasma is an ionized gas. Accordingly, in some embodiments, the plasma treatment comprises exposure to an ionized gas or plasma ions.

Plasma treatment can be done for every cycle of deposition or after a certain thickness is attained (e.g., 10 Å to 50 Å). In some embodiments, the plasma comprises one or more of Ar, N₂, H₂, He and ammonia. Plasma treatment can be done in the same chamber or by using a separate chamber mounted on the same mainframe. Plasma treatment may be done without exposure to air which oxidizes the film deposited at low temperatures (e.g., less than 500° C.), unless oxidation is desired. The film can also be treated by radicals of the above species generated by remote plasma source. Alternatively, the radicals can be generated by exposing the gas to a thermal element (e.g., a hot wire). The film treatment can be done at temperatures independent of the deposition treatment (e.g., 20° C. to 800° C.). In another aspect, halide chemistry is reacted with radicals of N₂, ammonia, H₂ or combinations thereof, to form the film. Radicals of these species are generated by use of a thermal element.

During processing of a semiconductor device, it is important to remain below the thermal budget of the device. Going beyond the thermal budget will likely result in a failing device. Therefore, it is desirable to process semiconductor devices at the lowest temperatures possible. It is known in the art that silicon nitride films formed at low temperature (e.g., less than 500° C.) have performance issues. For example, the wet etch rate of these films is high (i.e., in the range of about 200 Å/min to about 300 Å/min), the leakage current is high (i.e., 1010-1011 Å/cm²) and the breakdown voltage is too low (i.e., about 5 MV). The same is true for low temperature depositions of silicon carbide (SiC) and silicon carbonitride (SiCN) films. The inventors have discovered a method of depositing a film (e.g., silicon nitride) at low temperatures with excellent performance characteristics.

In some cases plasma treatment can catalyze a thermal reaction otherwise not possible at low temperature. For example, there is little or no thermal reaction between dichlorosilane and ammonia at 400° C. However, the Inventors have surprisingly discovered that when the surface is exposed to Ar+N₂ plasma before and or after NH₃ exposure, the reaction can occur. Additionally, the deposited film is SiN with a good wet etch rate and other film properties. Plasma treatment can be done every cycle or every few cycles and different gases can be used.

In an exemplary embodiment of the invention, a substrate surface is exposed to HCDS. Next, the substrate surface is exposed to ammonia. After this, the substrate surface is exposed to a plasma comprising Ar+N₂ (i.e., to obtain N* and/or NH* radicals).

In another exemplary embodiment of the invention, a substrate surface exposed to HCDS. Next, the substrate surface is exposed to ammonia. After this, the substrate surface is heated via a hot wire.

In another exemplary embodiment of the invention, a substrate surface exposed to DCS. Next, the substrate surface is exposed to ammonia. After this, the substrate surface is heated via a hot wire. After this, the substrate surface is exposed to a plasma comprising Ar+N₂ (i.e., to obtain N* and/or NH* radicals).

Accordingly, another aspect of the invention pertains to a method of forming a film on a substrate in a processing chamber, the method comprising: sequentially exposing the substrate to a first reactive gas comprising dichlorosilane or hexachlorodisilane and a second reactive gas comprising ammonia to form a film; and densifying the film with a densifying gas comprising one or more of a plasma and radicals to form a densified film and/or exposing the film to heat from a hot wire, wherein the film is formed at a temperature less than about 500° C.

In one or more embodiments, the film is densifying the film with a densifying gas comprising one or more of a plasma and radicals to form a densified film. In some embodiments, the plasma comprises Ar and N₂. In one or more embodiments, the plasma contains N* radicals. In some embodiments, exposing the film to heat from a hot wire produces N* and/or NH* radicals.

In one or more embodiments, ions and/or radicals are formed during the processes described herein. In one or more embodiments, plasmas act as both an ion and radical source. In some embodiments, the hotwire acts as only a radical source. While not wishing to be bound to any particular theory, it is thought that ions are advantageous for densified film deposition. Otherwise, films may be deposited, but will not be simultaneously densified.

One or more embodiments of the invention are directed to methods of forming a film on a substrate, or a portion of a substrate. The substrate is exposed to a first reactive gas to cause the first reactive gaseous species to be absorbed onto the surface of the substrate. The absorbed species can form a film or be simply absorbed molecules. The adsorbed species is then exposed to a second reactive gaseous species which reacts with the adsorbed species to form a film. After the film is formed, or at the same time as formation of the film, the film or adsorbed species are exposed to one or more of a plasma and radicals to cause the film to be densified.

One or more embodiments of the invention are directed to methods of forming a film on a substrate in a processing chamber. The substrate is sequentially exposed to a first reactive gas and a second reactive gas to form a film on the substrate. The film is then exposed to one or more of a plasma and radicals to densify the film.

In some embodiments, the first reactive gas comprises a silicon-containing species. In some embodiments, the second reactive gas comprises a reducing agent. In one or more embodiments, the second reactive gas comprises an oxidizing agent. In some embodiments, a combination of a first reactive gas comprising a silicon-containing species and second reactive gas comprising one or more of a reducing agent and an oxidizing agent results in the formation of a silicon nitride, silicon carbide or silicon carbonitride film on the substrate. After formation of the film, the film is exposed to one or more of a plasma and radicals of a third gas to form densify the film.

The first reactive gas can be any suitable reactive gas for use in atomic layer deposition reactions. In some embodiments, the first reactive gas comprises a silicon-containing gas. Suitable silicon-containing gases include, but are not limited to, silicon halides, monochlorosilane (MCS), dichlorosilane (DCS), hexachlorodisilane (HCDS), octachlorotrisilane (OCTS), and mixtures thereof.

The second reactive gas can be any suitable reactive gas capable of reacting with the first species which has been adsorbed onto the substrate surface. In some embodiments, the second reactive gas comprises a reducing agent, also referred to as a reductant. Suitable reducing agents include, but are not limited to, ammonia and hydrazine. In one or more embodiments, the second reactive gas is an oxidizer. Oxidizers may be useful for the deposition of, for example, oxynitride films. Suitable oxidizers include, but are not limited to N radicals, N₂O, NO and mixtures thereof.

The film formed by the combination of the first reactive gas and the second reactive gas is densified by exposure to one or more of a plasma and radical species. The plasma or gaseous species used can be the same as the second reactive gas or different from the second reactive gas. In some embodiments, this process may be referred to as a plasma-enhanced atomic layer deposition process (PEALD). The third gas, also referred to as the densifying gas, can be the second reactive gas or a separate gas, depending on the specific process. For example, the substrate may be exposed to silicon chloride (first reactive gas) followed by ammonia (second reactive gas) followed by an argon plasma (densifying gas). In this example, the third gas is separate from the second reactive gas both in chemical identity and exposure sequence. In another example, the substrate can be exposed to a first reactive gas comprising silicon chloride followed by exposure to a nitrogen plasma or nitrogen radicals. In this example, the densified film is formed in a single ALD cycle. Suitable examples of the densifying gas include, but are not limited to, argon, nitrogen, hydrogen, helium, ammonia and combinations thereof. In some embodimetns, the densifying gas is a mixture of Ar/N₂ or Ar/H₂ or Ar/He or Ar/NH₃ or N₂/H₂ or N₂/He or N₂/NH₃ or H₂/He or H₂/NH₃ or Ar/N₂/NH₃ or Ar/N₂/He or Ar/N₂/H₂ or He/N₂/H₂. The ratio of the mixed gases can vary depending on the first and second reactive gases and the processing conditions. In some embodiments, the densifying gas is a mixture of Ar/N₂ in a ratio in the range of about 1:1 to about 20:1.

The plasma can be either a direct plasma or a remote plasma. A direct plasma is a plasma that is ignited within the processing chamber, or within the processing region adjacent the substrate. Igniting a plasma immediately adjacent the substrate may cause damage to the substrate, depending on the conditions of the plasma. A remote plasma is formed away from the substrate and is flowed into the processing region of the chamber. Since the remote plasma is generated away from the substrate there is little chance that the substrate will be damaged by ignition of the plasma. However, ions formed in a remote plasma must have a longer lifetime to interact with the substrate because the ions have to be flowed to the substrate. Accordingly, there are advantages to both direct and remote plasmas and either or both can be used.

Without being bound by any particular theory of operation, it is believed that densifying the film causes the molecules to rearrange and/or to replace hydrogen atoms with nitrogen atoms, modifying the structure of the film. Additionally, as the term implies, densifying the film causes an increase in the density of atoms in the film. It is believed that the densification of the film can decrease or eliminate the negative effects of low temperature depositions. In some embodiments, the film is formed at a temperature less than about 500° C. In one or more embodiments, the film is formed at a temperature less than about 450° C., 400° C., 350° C., 300° C., 250° C. or 200° C. In some embodiments a silicon nitride, silicon carbide and/or silicon carbonitride film is formed at a temperature less than about 500° C. In one or more embodiments, the silicon nitride, silicon carbide and/or silicon carbonitride film is formed at a temperature less than about 450° C., 400° C., 350° C., 300° C., 250° C. or 200° C.

In addition to being able to deposit the film at low temperatures, the film can be densified at low temperatures. The combination of low temperature deposition and low temperature densification can result in a significant savings to the thermal budget of the device. In one or more embodiments, the film is densified at a temperature less than about 50° C. In some embodiments, the film is densified at a temperature in the range of about 0° C. to about 50° C., or in the range of about 5° C. to about 45° C., or in the range of about 10° C. to about 40° C., or in the range of about 15° C. to about 35° C. or in the range of about 20° C. to about 30° C. or at about room temperature. Densification by exposure to room temperature plasma preserves the thermal budget, is easier to maintain the plasma and is less expensive to process.

The pressure may be varied depending on the specific reaction conditions and precursors utilized. There are at least two options for pressure conditions during deposition. In one or more embodiments, the pressure during the deposition process is relatively low throughout the deposition process, particularly so for embodiments relating to plasma (although possibly also for hot wire embodiments). In such embodiments, the pressure during deposition may be less than 50, 40, 30, 20, 15 or 10 Torr, and/or greater than about 3, 4, 5, 6, 8, 10 or 15 Torr.

In other embodiments, the pressure is relatively high during deposition, and then lowered during densification. The process can then be repeated until a desired film thickness is achieved. In these embodiments, pressure during deposition may range from about 30 or 35 Torr to about 45 or 50, 60, 70 or 80 Torr. In further embodiments, the pressure during deposition may be 40 Torr. In these embodiments, pressure during densification may be less than 10 12, 14 or 15 Torr and/or greater than about 6. In some embodiments, the pressure during densification may range from about 6, 8 or 10 to about 12, or 15 Torr.

In one or more embodiments, the substrate surface may be exposed to a pre-treatment. In further embodiments, the pre-treatment include exposure to an Ar plasma. In some embodiments, the plasma is a different plasma than used during deposition.

In some embodiments, the deposited film is exposed to a densifying gas comprising radical gaseous species instead of, or in addition to, a plasma of the gaseous species. The radical species can be generated in a plasma or by passing the densifying gas across a thermal element. The thermal element, also referred to as a hot wire, elevates the temperature of the gaseous species to cause radicalization of some of the gaseous species. To preserve the thermal budget of the resulting device, the thermal element may be operated at or near the lowest temperature required for sufficient radicalization of the gaseous species. Additionally, the hot wire, or thermal element, can be positioned remotely from the substrate surface. The radicals generated might have a longer lifetime, or greater degree of radicalization, due to the potential for relaxation to the ground state.

Densification of the film can be performed with or without exposure of the film to ambient conditions. As used in this specification and the appended claims, the term “ambient conditions,” and the like, refer to the conditions of the laboratory or manufacturing facility environment. While the film may be exposed to ambient conditions prior to densification, many films degrade upon exposure to air. Therefore, it may be desirable to avoid exposure to the ambient environment. In some embodiments, the film is densified without exposure of the film to ambient conditions. This can be done by densifying the film in the same processing chamber used to deposit the film or in a clustered tool where the substrate can be moved between processing chambers without being exposed to ambient conditions. The various processing chambers and cluster tools are described further below.

In some embodiments, the film is formed by atomic layer deposition followed by densification after each exposure to the first reactive gas and the second reactive gas. Therefore, after each ALD layer, or partial layer, is formed, the film is densified. Again, without being bound by any particular theory of operation, it is believed that densification of a thinner film will proceed faster than for a thicker film. An exemplary process comprise exposing the substrate to a first reactive gas followed by a second reactive gas followed by a densifying gas, and repeating the process to form a densified film of the desired thickness. In some embodiments, there are several ALD cycles performed before densification. This may be useful where the densification process occurs rapidly on thin films so that there is no or little advantage to densification after each deposition. In one or more embodiments, the film is densified after forming a film having a thickness in the range of about 1 Å to about 100 Å, or in the range of about 1 Å to about 50 Å, or in the range of about 5 Å to about 50 Å, or when the film has a thickness greater than about 5 Å, or greater than about 10 Å, or greater than about 15 Å, or greater than about 20 Å.

The total thickness of the film can vary depending on the specific film being deposited. In some embodiments, the film formed is silicon nitride, silicon carbide and/or silicon carbonitride and the total thickness is in the range of about 10 Å to about 500 Å, or up to about 1000 Å, or up to about 500 Å, or up to about 400 Å, or up to about 300 Å, or up to about 200 Å.

In one or more embodiments, the processes described herein produce films with relatively low etch rates. Many conventional processes have wet etch rates well above 100 Å/minute. In some embodiments, a densified silicon nitride, silicon carbide and/or silicon carbonitride film formed has a wet etch rate less than about 150 Å/minute, or less than about 100 Å/minute. In some embodiments, the etch rate is less than about 5:1, 1:1, or 0.5:1, 0.4:1, 0.3:1, 0.2:1, 0.1:1, or less than about 0.5:1 relative to thermal SiO₂. In one or more embodiments, a silicon nitride, silicon carbide and/or silicon carbonitride film formed and densified has a lower wet etch rate than a similarly prepared silicon nitride, silicon carbide and/or silicon carbonitride film formed without the densification.

In some embodiments, a densified silicon nitride, silicon carbide and/or silicon carbonitride film formed has a leakage current less than about 5×10⁹ Å/cm², or less than about 4×10⁹ Å/cm², or less than about 3×10⁹ Å/cm², or less than about 2×10⁹ Å/cm², or less than about 1×10⁹ Å/cm². In one or more embodiments, the silicon nitride, silicon carbide and/or silicon carbonitride film formed and densified has a lower leakage current than a similarly prepared silicon nitride, silicon carbide and/or silicon carbonitride film formed without densification.

In some embodiments, a densified silicon nitride, silicon carbide and/or silicon carbonitride film formed has a breakdown voltage greater than about 7 MV, or greater than about 8 MV or greater than about 9 MV. In one or more embodiments, the silicon nitride, silicon carbide and/or silicon carbonitride film formed and densified has a high breakdown voltage than a similarly prepared silicon nitride, silicon carbide and/or silicon carbonitride film formed without densification.

In one or more embodiments, a silicon nitride film is formed and densified by sequential exposure to hexachlorodisilane and ammonia at a temperature about 400° C. followed by densification by exposure to an argon/nitrogen plasma at room temperature. The sequence is repeated until the desired densified silicon nitride film thickness is formed.

FIG. 1 is a schematic cross-sectional view of an atomic layer deposition system or system 100 in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution plate 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution plates may be employed.

Atomic layer deposition systems of this sort (i.e., where multiple gases are separately flowed to the substrate at the same time) may be referred to as spatial ALD. In operation, a substrate 60 is delivered (e.g., by a robot) to the load lock chamber 10 and is placed on a shuttle 65. After the isolation valve 15 is opened, the shuttle 65 is moved along the track 70. Once the shuttle 65 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps.

Sufficient space is generally provided at the end of the processing chamber 20 so as to ensure complete exposure by the last gas port in the processing chamber 20 and other processing equipment. Once the substrate 60 reaches the end of the processing chamber 20 (i.e., the first surface 61 has completely been exposed to every gas port in the processing chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

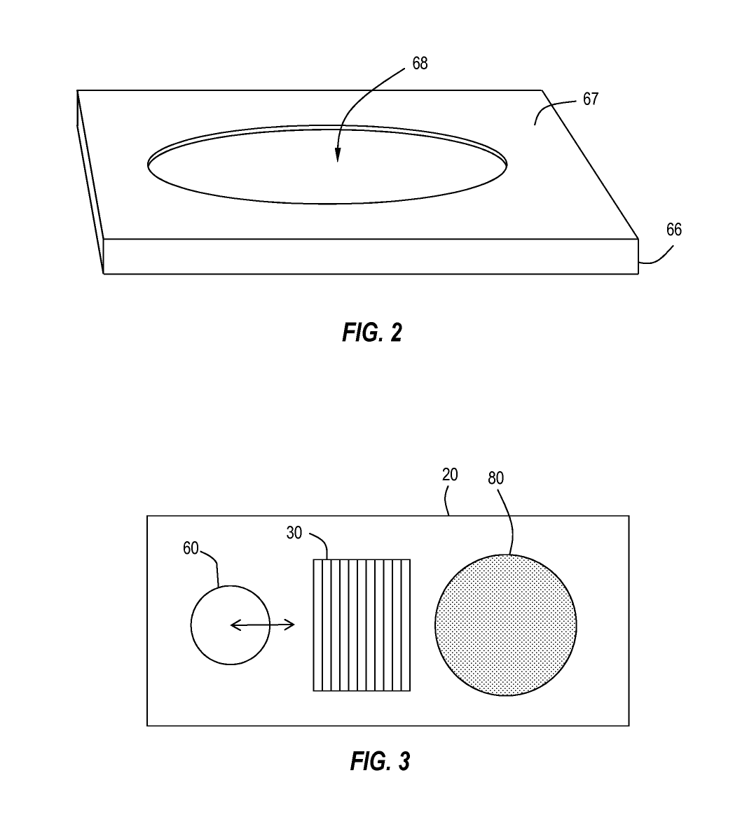

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66.

In some embodiments, the substrate is thermally isolated from the carrier to minimize heat losses. This can be done by any suitable means, including but not limited to, minimizing the surface contact area and using low thermal conductance materials.

Substrates have an inherent thermal budget which is limited based on previous processing done on the substrate and any planned or potential future processing. Therefore, it is useful to limit the exposure of the substrate to large prolonged temperature variations to avoid exceeding this thermal budget, thereby damaging the previous processing.

FIG. 3 shows an embodiment of a processing system 20 with a substrate 60, a gas distribution plate 30 and a post-processing device 80. A post-processing device 80 can be another showerhead, gas distribution plate or other device for introducing a plasma or gaseous species to the substrate. The gas distribution plate 30 can be any suitable gas distribution plate including the spatial ALD gas distribution plate of FIG. 1 or a traditional vortex lid or showerhead. In use, the substrate 60 moves adjacent the gas distribution plate 30 for ALD processing. After the desired number of atomic layers have been deposited, the substrate 60 is moved adjacent the post-processing device 80 where the deposited film is subjected to one or more of exposure to plasma or radical species to densify or otherwise modify the film. The chamber 20 of FIG. 3 shows minimal components in a broad description and should not be taken as limiting the scope of the invention. The chamber 20 may include other components including, but not limited to, partitions to act as separations between the gas distribution plate 30 and the post-processing device 80, gas inlets and exhaust ports.

In some embodiments, the gas distribution plate 30 includes at least one post-processing device 80 to cause local exposure of the surface or a portion of the substrate 60 to one or more of a plasma and a radicalized gaseous species. The local exposure affects primarily a portion of the surface of the substrate 60 without affecting the bulk of the substrate.

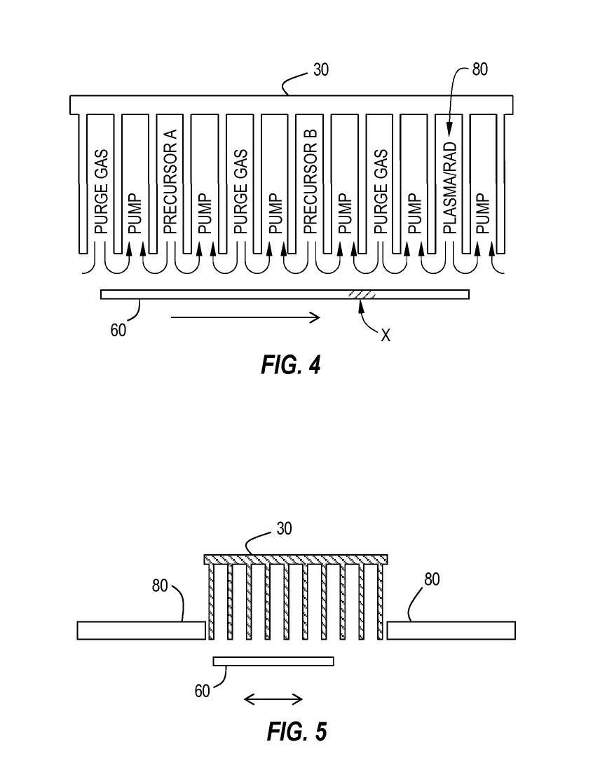

FIG. 4 shows an embodiment of a spatial ALD gas distribution plate including in-line plasma/radical processing. In operation, the substrate 60 moves relative to the gas ports of the gas distribution plate 30, as shown by the arrow. Region X moves past gas ports with purge gases, vacuum ports and a first precursor A port, where the surface of the substrate 60 reacts with the first precursor A. A substrate can be processed by being exposed substantially simultaneously to the first reactive gas and the second reactive gas with substantially no gas-phase mixing of the first reactive gas and the second reactive gas. As used in this specification and the appended claims, the term “substantially no gas-phase mixing” means that while the individual gases are removed from the processing region adjacent the substrate before they can react, those skilled in the art will understand that there may still be some small degree of molecular diffusion of the gaseous species allowing the species to react in the gas phase. Additionally, the term “substantially no gas-phase mixing” refers to the processing region adjacent the substrate, not to areas outside the processing region (e.g., in exhaust lines).

It will be understood by those skilled in the art that, as used and described herein, region X is an artificially fixed point or region of the substrate. In actual use in a spatial ALD process, the region X would be, literally, a moving target, as the substrate is moving adjacent and relative to the gas distribution plate 30. For descriptive purposes, the region X shown is at a fixed point.

In some embodiments, the region X, which is also referred to as a portion of the substrate is limited in size. In some embodiments, the portion of the substrate effected by any individual thermal element is less than about 20% of the area of the substrate. In various embodiments, the portion of the substrate effected by any individual thermal element is less than about 15%, 10%, 5% or 2% of the area of the substrate.

FIGS. 4-7 show various gas distribution plates 30 and post-processing device 80 placements. It should be understood that these examples are merely illustrative of some embodiments of the invention and should not be taken as limiting the scope of the invention. In some embodiments, the post-processing device 80 is positioned within at least one elongate gas port. Embodiments of this variety are shown in FIG. 4. In FIG. 4, the post-processing device 80 is a gas injector in the gas distribution plate 30. The post-processing device 80 can be an injector which provides a flow of a plasma of ionized gaseous species or radicals to the substrate surface. The plasma can be generated within the gas port, or directly beneath the gas port, or remotely from the gas distribution plate 30. A remote plasma incorporates a separate plasma generating unit in fluid communication with the gas distribution plate.

In some embodiments, the post-processing device 80 comprises a thermal element, or hot wire, which is capable of creating radicals in the gas flowing across the thermal element. The thermal element can be a bare metal wire of any suitable shape. For example, the thermal element can be substantially straight, helical, curved or otherwise patterned. In some embodiments, tension is provided on the ends of the thermal element to minimize sagging of the thermal element during processing. More than one thermal element can be included in a single post-processing device. For example, a first thermal element may be a substantially straight wire with a second thermal element being helical and wrapped around the first thermal element so that the two thermal elements do not touch each other.

Additionally, the thermal element can be encased in a protective shell. For example, the thermal element may be contained within a quartz tube to prevent the gaseous species from directly contacting the thermal element. In embodiments of this sort, the thermal element heats the quartz tube sufficiently to generate radicals within the gas passing across the quartz tube.

It will be understood by those skilled in the art that there can be more than one post-processing device 80 in any given gas distribution plate 30. An example of this would be a gas distribution plate 30 with two repeating units of precursor A, precursor B and plasma/radical source.

The post-processing device 80 may be positioned before and/or after the gas distribution plate 30, as shown in FIG. 5. These embodiments are suitable for both reciprocal processing chambers in which the substrates moves back and forth adjacent the gas distribution plate, and in continuous (carousel or conveyer) architectures. In some embodiments the post-processing device 80 comprises a showerhead or vortex lid. The showerhead or vortex lid can be used with a direct plasma or remote plasma. In the embodiment shown in FIG. 5, there are two thermal elements 80, one on either side of the gas distribution plate, so that in reciprocal type processing, the substrate 60 is exposed to the post-processing device in both processing directions.

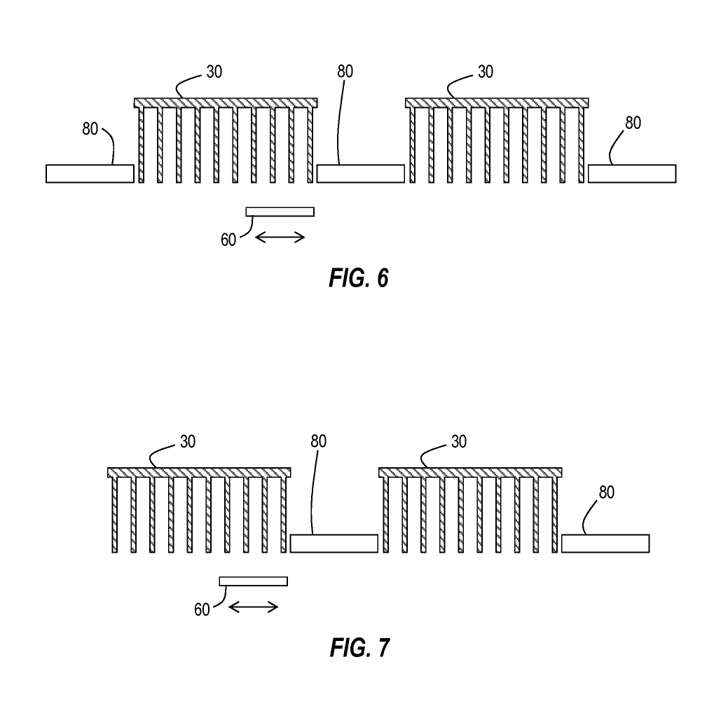

FIG. 6 shows another embodiment of the invention in which there are two gas distribution plates 30 with thermal elements 80 before, after and between each of the gas distribution plates 30. This embodiment is of particular use with reciprocal processing chambers as it allows for more layers to be deposited in a single cycle (one pass back and forth). Because there is a post-processing device 80 at the beginning and end of the gas distribution plates 30, the substrate 60 is affected by the post-processing device 80 after passing the gas distribution plate 30 in either the forward (e.g., left-to-right) or reverse (e.g., right-to-left) movement. It will be understood by those skilled in the art that the processing chamber 20 can have any number of gas distribution plates 30 with thermal elements 80 before and/or after each of the gas distribution plates 30 and the invention should not be limited to the embodiments shown.

FIG. 7 shows another embodiment similar to that of FIG. 6 with the post-processing device 80 after each gas distribution plate 30. Embodiments of this sort are of particular use with continuous processing, rather than reciprocal processing. For example, the processing chamber 20 may contain any number of gas distribution plates 30 with a post-processing device 80 before each plate.

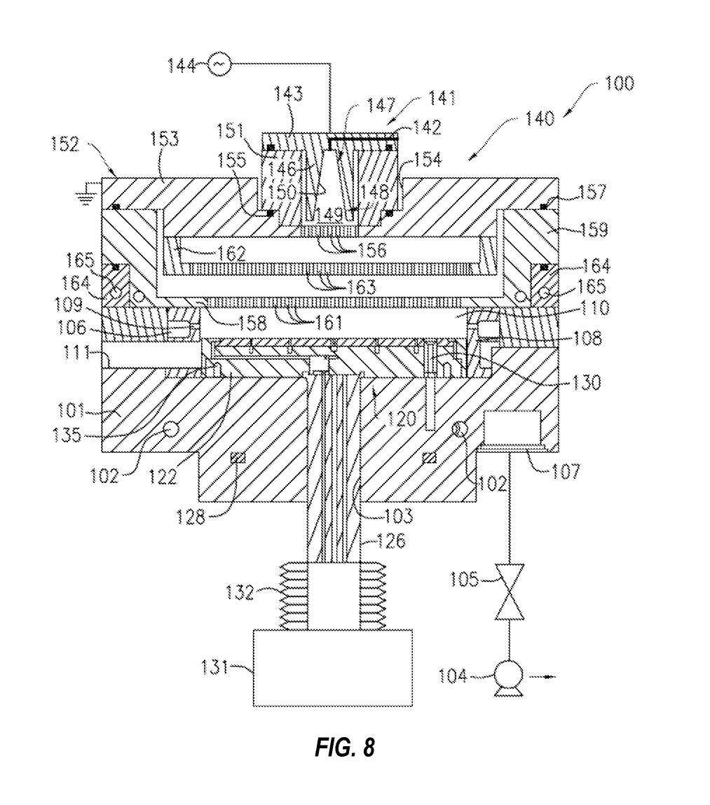

FIG. 8 is a partial cross sectional view showing a processing chamber 100 suitable for use with time-domain type atomic layer deposition. As used in this specification and the appended claims, the term “time-domain” refers to a process by which a single reactive gas is injected into the processing chamber at a time and purged before another reactive gas is injected. This prevents the gas-phase reaction of the reactive gases within the processing chamber and effectively limits the reactions to surface-based reactions. The processing chamber 100 may include a chamber body 101, a lid assembly 140, and a support assembly 120, also referred to as a substrate support. The lid assembly 140 is disposed at an upper end of the chamber body 101, and the support assembly 120 is at least partially disposed within the chamber body 101. The chamber body 101 may include a slit valve opening 111 formed in a sidewall thereof to provide access to the interior of the processing chamber 100. The slit valve opening 111 is selectively opened and closed to allow access to the interior of the chamber body 101 by a robot (not shown).

It will be understood by those skilled in the art that the descriptions of the components below may also be applicable for spatial ALD processing chambers. The chamber body 101 may include a channel 102 formed therein for flowing a heat transfer fluid therethrough. The heat transfer fluid can be a heating fluid or a coolant and is used to control the temperature of the chamber body 101 during processing and substrate transfer. Exemplary heat transfer fluids include water, ethylene glycol, or a mixture thereof. An exemplary heat transfer fluid may also include nitrogen gas.

The chamber body 101 can further include a liner 108 that surrounds the support assembly 120. The liner 108 is preferably removable for servicing and cleaning. The liner 108 can be made of a metal such as aluminum, or a ceramic material. However, the liner 108 can be any process compatible material. The liner 108 can be bead blasted to increase the adhesion of any material deposited thereon, thereby preventing flaking of material which results in contamination of the processing chamber 100. The liner 108 may include one or more apertures 109 and a pumping channel 106 formed therein that is in fluid communication with a vacuum system. The apertures 109 provide a flow path for gases into the pumping channel 106, which provides an egress for the gases within the processing chamber 100.

The vacuum system can include a vacuum pump 104 and a throttle valve 105 to regulate flow of gases through the processing chamber 100. The vacuum pump 104 is coupled to a vacuum port 107 disposed on the chamber body 101 and therefore is in fluid communication with the pumping channel 106 formed within the liner 108.

Apertures 109 allow the pumping channel 106 to be in fluid communication with a processing zone 110 within the chamber body 101. The processing zone 110 is defined by a lower surface of the lid assembly 140 and an upper surface of the support assembly 120, and is surrounded by the liner 108. The apertures 109 may be uniformly sized and evenly spaced about the liner 108. However, any number, position, size or shape of apertures may be used, and each of those design parameters can vary depending on the desired flow pattern of gas across the substrate receiving surface as is discussed in more detail below. In addition, the size, number and position of the apertures 109 are configured to achieve uniform flow of gases exiting the processing chamber 100. Further, the aperture size and location may be configured to provide rapid or high capacity pumping to facilitate a rapid exhaust of gas from the chamber 100. For example, the number and size of apertures 109 in close proximity to the vacuum port 107 may be smaller than the size of apertures 109 positioned farther away from the vacuum port 107.

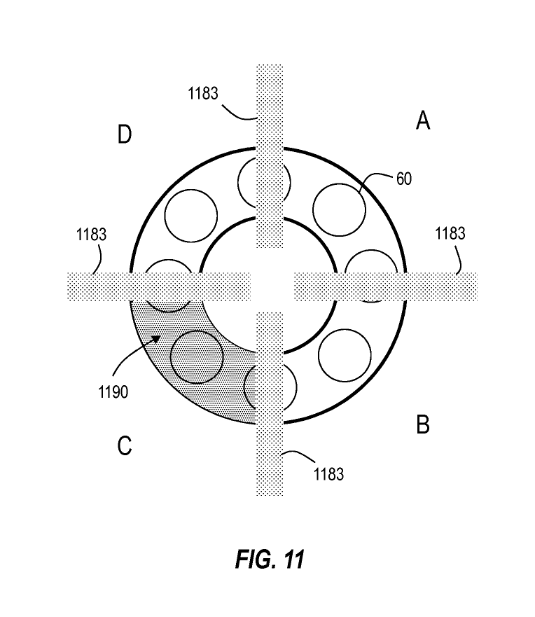

Considering the lid assembly 140 in more detail, FIG. 11 shows an enlarged cross sectional view of lid assembly 140 that may be disposed at an upper end of the chamber body 101. The lid assembly 140 may include a first electrode 141 (“upper electrode”) disposed vertically above a second electrode 152 (“lower electrode”) confining a plasma volume or cavity 149 therebetween. The first electrode 141 is connected to a power source 144, such as an RF power supply, and the second electrode 152 is connected to ground, forming a capacitance between the two electrodes 141, 152.

The lid assembly 140 may include one or more gas inlets 142 (only one is shown) that are at least partially formed within an upper section 143 of the first electrode 141. One or more process gases enter the lid assembly 140 via the one or more gas inlets 142. The one or more gas inlets 142 are in fluid communication with the plasma cavity 149 at a first end thereof and coupled to one or more upstream gas sources and/or other gas delivery components, such as gas mixers, at a second end thereof. The first end of the one or more gas inlets 142 may open into the plasma cavity 149 at the upper-most point of the inner diameter 150 of expanding section 146. Similarly, the first end of the one or more gas inlets 142 may open into the plasma cavity 149 at any height interval along the inner diameter 150 of the expanding section 146. Although not shown, two gas inlets 142 can be disposed at opposite sides of the expanding section 146 to create a swirling flow pattern or “vortex” flow into the expanding section 146 which helps mix the gases within the plasma cavity 149.

The first electrode 141 may have an expanding section 146 that houses the plasma cavity 149. The expanding section 146 may be in fluid communication with the gas inlet 142 as described above. The expanding section 146 may be an annular member that has an inner surface or diameter 150 that gradually increases from an upper portion 147 thereof to a lower portion 148 thereof. As such, the distance between the first electrode 141 and the second electrode 152 is variable. That varying distance helps control the formation and stability of the plasma generated within the plasma cavity 149.

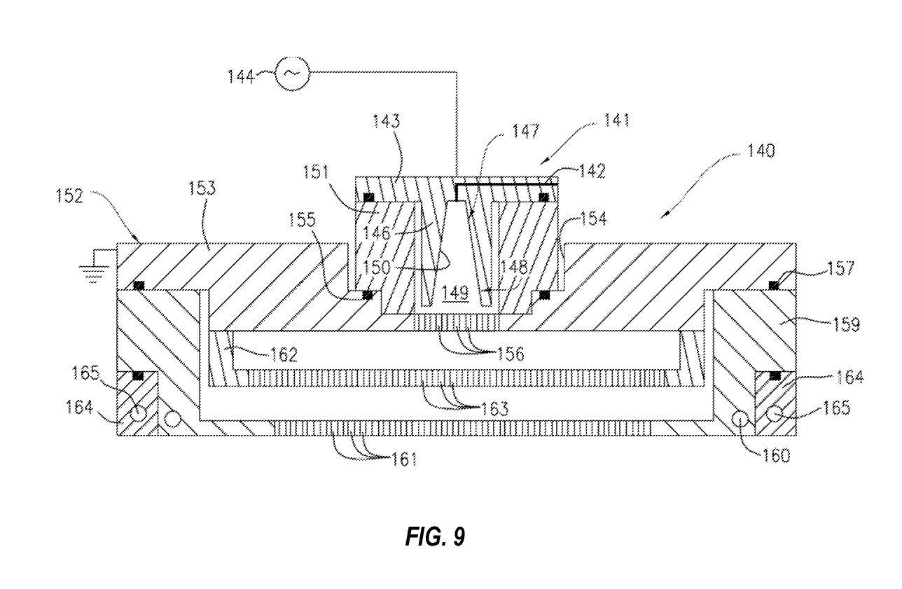

The expanding section 146 may resemble a cone or “funnel,” as is shown in FIGS. 8 and 9. The inner surface 150 of the expanding section 146 may gradually slope from the upper portion 147 to the lower portion 148 of the expanding section 146. The slope or angle of the inner diameter 150 can vary depending on process requirements and/or process limitations. The length or height of the expanding section 146 can also vary depending on specific process requirements and/or limitations. The slope of the inner diameter 150, or the height of the expanding section 146, or both may vary depending on the volume of plasma needed for processing.

Not wishing to be bound by theory, it is believed that the variation in distance between the two electrodes 141, 152 allows the plasma formed in the plasma cavity 149 to find the necessary power level to sustain itself within some portion of the plasma cavity 149, if not throughout the entire plasma cavity 149. The plasma within the plasma cavity 149 is therefore less dependent on pressure, allowing the plasma to be generated and sustained within a wider operating window. As such, a more repeatable and reliable plasma can be formed within the lid assembly 140.

The first electrode 141 can be constructed from any process compatible materials, such as aluminum, anodized aluminum, nickel plated aluminum, nickel plated aluminum 6061-T6, stainless steel as well as combinations and alloys thereof, for example. In one or more embodiments, the entire first electrode 141 or portions thereof are nickel coated to reduce unwanted particle formation. Preferably, at least the inner surface 150 of the expanding section 146 is nickel plated.

The second electrode 152 can include one or more stacked plates. When two or more plates are desired, the plates should be in electrical communication with one another. Each of the plates should include a plurality of apertures or gas passages to allow the one or more gases from the plasma cavity 149 to flow through.

The lid assembly 140 may further include an isolator ring 151 to electrically isolate the first electrode 141 from the second electrode 152. The isolator ring 151 can be made from aluminum oxide or any other insulative, process compatible material. Preferably, the isolator ring 151 surrounds or substantially surrounds at least the expanding section 146.

The second electrode 152 may include a top plate 153, distribution plate 158 and blocker plate 162 separating the substrate in the processing chamber from the plasma cavity. The top plate 153, distribution plate 158 and blocker plate 162 are stacked and disposed on a lid rim 164 which is connected to the chamber body 101. As is known in the art, a hinge assembly (not shown) can be used to couple the lid rim 164 to the chamber body 101. The lid rim 164 can include an embedded channel or passage 165 for housing a heat transfer medium. The heat transfer medium can be used for heating, cooling, or both, depending on the process requirements.

The top plate 153 may include a plurality of gas passages or apertures 156 formed beneath the plasma cavity 149 to allow gas from the plasma cavity 149 to flow therethrough. The top plate 153 may include a recessed portion 154 that is adapted to house at least a portion of the first electrode 141 or a recessed portion 154 to house at least a portion of the first electrode. In one or more embodiments, the apertures 156 are through the cross section of the top plate 153 beneath the recessed portion 154. The recessed portion 154 of the top plate 153 can be stair stepped as shown in FIG. 9 to provide a better sealed fit therebetween. Furthermore, the outer diameter of the top plate 153 can be designed to mount or rest on an outer diameter of the distribution plate 158 as shown in FIG. 9. An o-ring type seal, such as an elastomeric o-ring 155, can be at least partially disposed within the recessed portion 154 of the top plate 153 to ensure a fluid-tight contact with the first electrode 141. Likewise, an o-ring type seal 157 can be used to provide a fluid-tight contact between the outer perimeters of the top plate 153 and the distribution plate 158.

The distribution plate 158 is substantially disc-shaped and includes a plurality of apertures 161 or passageways to distribute the flow of gases therethrough. The apertures 161 can be sized and positioned about the distribution plate 158 to provide a controlled and even flow distribution to the processing zone 110 where the substrate 70 to be processed is located. Furthermore, the apertures 161 prevent the gas(es) from impinging directly on the substrate 70 surface by slowing and re-directing the velocity profile of the flowing gases, as well as evenly distributing the flow of gas to provide an even distribution of gas across the surface of the substrate 70.

The distribution plate 158 can also include an annular mounting flange 159 formed at an outer perimeter thereof. The mounting flange 159 can be sized to rest on an upper surface of the lid rim 164. An o-ring type seal, such as an elastomeric o-ring, can be at least partially disposed within the annular mounting flange 159 to ensure a fluid-tight contact with the lid rim 164.

The distribution plate 158 may include one or more embedded channels or passages 160 for housing a heater or heating fluid to provide temperature control of the lid assembly 140. A resistive heating element can be inserted within the passage 160 to heat the distribution plate 158. A thermocouple can be connected to the distribution plate 158 to regulate the temperature thereof. The thermocouple can be used in a feedback loop to control electric current applied to the heating element, as known in the art.

Alternatively, a heat transfer medium can be passed through the passage 160. The one or more passages 160 can contain a cooling medium, if needed, to better control temperature of the distribution plate 158 depending on the process requirements within the chamber body 101. As mentioned above, any heat transfer medium may be used, such as nitrogen, water, ethylene glycol, or mixtures thereof, for example.

The lid assembly 140 may be heated using one or more heat lamps (not shown). Typically, the heat lamps are arranged about an upper surface of the distribution plate 158 to heat the components of the lid assembly 140 including the distribution plate 158 by radiation.

The blocker plate 162 is optional and may be disposed between the top plate 153 and the distribution plate 158. Preferably, the blocker plate 162 is removably mounted to a lower surface of the top plate 153. The blocker plate 162 should make good thermal and electrical contact with the top plate 153. The blocker plate 162 may be coupled to the top plate 153 using a bolt or similar fastener. The blocker plate 162 may also be threaded or screwed onto an out diameter of the top plate 153.

The blocker plate 162 includes a plurality of apertures 163 to provide a plurality of gas passages from the top plate 153 to the distribution plate 158. The apertures 163 can be sized and positioned about the blocker plate 162 to provide a controlled and even flow distribution the distribution plate 158.

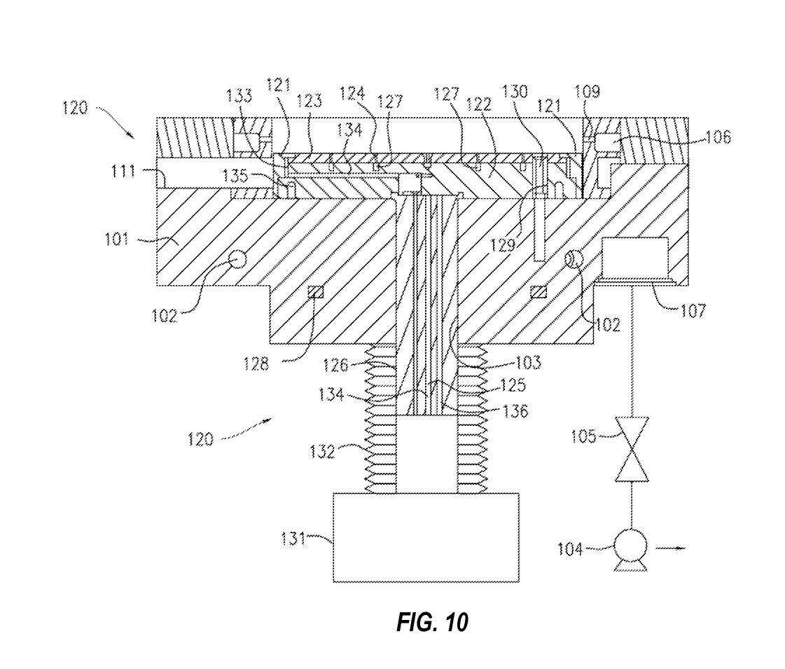

FIG. 10 shows a partial cross sectional view of an illustrative support assembly 120 or substrate support. The support assembly 120 can be at least partially disposed within the chamber body 101. The support assembly 120 can include a support member 122 to support the substrate 70 (not shown in this view) for processing within the chamber body 101. The support member 122 can be coupled to a lift mechanism 131 through a shaft 126 which extends through a centrally-located opening 103 formed in a bottom surface of the chamber body 101. The lift mechanism 131 can be flexibly sealed to the chamber body 101 by a bellows 132 that prevents vacuum leakage from around the shaft 126. The lift mechanism 131 allows the support member 122 to be moved vertically within the chamber body 101 between a process position and a lower, transfer position. The transfer position is slightly below the opening of the slit valve 111 formed in a sidewall of the chamber body 101.

In one or more embodiments, the substrate 70 (not shown in FIG. 10) may be secured to the support assembly 120 using a vacuum chuck. The top plate 123 can include a plurality of holes 124 in fluid communication with one or more grooves 127 formed in the support member 122. The grooves 127 are in fluid communication with a vacuum pump (not shown) via a vacuum conduit 125 disposed within the shaft 126 and the support member 122. Under certain conditions, the vacuum conduit 125 can be used to supply a purge gas to the surface of the support member 122 when the substrate 70 is not disposed on the support member 122. The vacuum conduit 125 can also pass a purge gas during processing to prevent a reactive gas or byproduct from contacting the backside of the substrate 70.

The support member 122 can include one or more bores 129 formed therethrough to accommodate a lift pin 130. Each lift pin 130 is typically constructed of ceramic or ceramic-containing materials, and are used for substrate-handling and transport. Each lift pin 130 is slideably mounted within the bore 129. The lift pin 130 is moveable within its respective bore 129 by engaging an annular lift ring 128 disposed within the chamber body 101. The lift ring 128 is movable such that the upper surface of the lift-pin 130 can be located above the substrate support surface of the support member 122 when the lift ring 128 is in an upper position. Conversely, the upper surface of the lift-pins 130 is located below the substrate support surface of the support member 122 when the lift ring 128 is in a lower position. Thus, part of each lift-pin 130 passes through its respective bore 129 in the support member 122 when the lift ring 128 moves from either the lower position to the upper position.

When activated, the lift pins 130 push against a lower surface of the substrate 70, lifting the substrate 70 off the support member 122. Conversely, the lift pins 130 may be de-activated to lower the substrate 70, thereby resting the substrate 70 on the support member 122.

The support assembly 120 can include an edge ring 121 disposed about the support member 122. The edge ring 121 is an annular member to cover an outer perimeter of the support member 122 and protect the support member 122. The edge ring 121 can be positioned on or adjacent the support member 122 to form an annular purge gas channel 133 between the outer diameter of support member 122 and the inner diameter of the edge ring 121. The annular purge gas channel 133 can be in fluid communication with a purge gas conduit 134 formed through the support member 122 and the shaft 126. Preferably, the purge gas conduit 134 is in fluid communication with a purge gas supply (not shown) to provide a purge gas to the purge gas channel 133. In operation, the purge gas flows through the conduit 134, into the purge gas channel 133, and about an edge of the substrate disposed on the support member 122. Accordingly, the purge gas working in cooperation with the edge ring 121 prevents deposition at the edge and/or backside of the substrate.

The temperature of the support assembly 120 is controlled by a fluid circulated through a fluid channel 135 embedded in the body of the support member 122. The fluid channel 135 may be in fluid communication with a heat transfer conduit 136 disposed through the shaft 126 of the support assembly 120. The fluid channel 135 may be positioned about the support member 122 to provide a uniform heat transfer to the substrate receiving surface of the support member 122. The fluid channel 135 and heat transfer conduit 136 can flow heat transfer fluids to either heat or cool the support member 122. The support assembly 120 can further include an embedded thermocouple (not shown) for monitoring the temperature of the support surface of the support member 122.

In operation, the support member 122 can be elevated to a close proximity of the lid assembly 140 to control the temperature of the substrate 70 being processed. As such, the substrate 70 can be heated via radiation emitted from the distribution plate 158 that is controlled by the heating element 474. Alternatively, the substrate 70 can be lifted off the support member 122 to close proximity of the heated lid assembly 140 using the lift pins 130 activated by the lift ring 128.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without a plasma.

FIG. 11 shows a schematic representation of a deposition chamber in accordance with another embodiment of the invention. In the embodiment shown, substrates 60 move in a circular path or a circular tunnel that is sectioned into multiple zones for precursors, purge and plasma/radical treatments. Multiple wafers can be processed as mini-batches and can pass the zones in a continuous circular motion to realize single wafer mini-batch processes. Every zone can be pumping to a central exhaust to evacuate unreacted gases. Each section of the path can be separated by air curtains 1183, or similar. The embodiment shown has a quarter of the circular path for heat treatment with a suitable heat treatment device 1190. For example, referring to FIG. 11, in zone A, the substrate 60 can be exposed to a silicon-containing first reactive gas. In zone B, the substrate 60 is then exposed to a second reactive gas comprising a reducing agent to form a silicon nitride, silicon carbide and/or silicon carbonitride film on the substrate. In zone C, which is referred to as the post-processing zone, the silicon nitride, silicon carbide and/or silicon carbonitride film is exposed to a plasma or radical species to densify the silicon nitride, silicon carbide and/or silicon carbonitride film. Zone D can be any other post-processing or pre-processing step, and the substrate may flow through the zones repeatedly. Those skilled in the art will understand that this is merely exemplary, and that other films can be formed.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

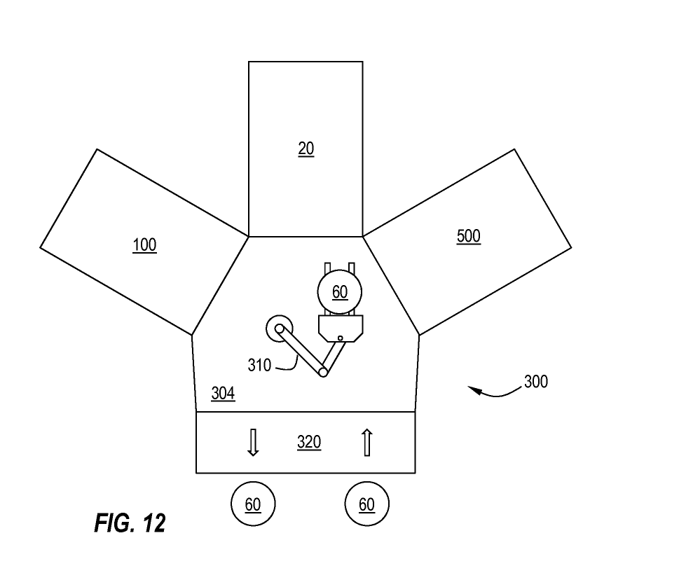

Referring to FIG. 12, an illustrative cluster tool 300 includes a central transfer chamber 304 generally including a multi-substrate robot 310 adapted to transfer a plurality of substrates in and out of the load lock chamber 320 and the various processing chambers. Although the cluster tool 300 is shown with processing chambers 20 which may be, for example, a spatial ALD processing chamber, processing chamber 100, which may be, for example, a time-domain ALD processing chamber and a third processing chamber 500, for example, a rapid thermal processing chamber, it will be understood by those skilled in the art that there can be more or less than 3 processing chambers. Additionally, the processing chambers can be for different types (e.g., ALD, CVD, PVD) of substrate processing techniques.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discrete steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

In some embodiments, additional processing is performed one or more of before and after the formation of the film on the substrate without exposing the substrate to the ambient environment. For example, cleaning processes, polishing

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming a film on a substrate in a processing chamber, the method comprising:
sequentially exposing the substrate to a first reactive gas comprising silicon and a second reactive gas comprising one or more of a reducing agent and an oxidizing agent to form a film selected from one or more of silicon nitride, silicon carbide and silicon carbonitride; and
densifying the film with a densifying gas comprising one or more of a plasma and radicals to form a densified film,
wherein the film is formed at a temperature less than about 500° C.

2. The method of claim 1, wherein the first reactive gas is a silicon halide.

3. The method of claim 1, wherein the second reactive gas comprises one or more of ammonia and hydrazine.

4. The method of claim 1, wherein the densifying gas is one or more of argon, nitrogen, hydrogen, helium, ammonia nitric oxide and nitrous oxide.

5. The method of claim 1, wherein the densifying gas is the second reactive gas and the densified film is formed at substantially the same time as the film.

6. The method of claim 1, wherein the film is densified without being exposed to ambient conditions.

7. The method of claim 1, wherein the densifying gas is a third gas different from the first reactive gas and the second reactive gas, and the film is exposed to a plasma of the third gas.

8. The method of claim 7, wherein exposure to the plasma occurs at a temperature of less than about 50° C.

9. The method of claim 7, wherein the plasma is formed remotely from the processing chamber.

10. The method of claim 7, wherein the plasma is formed within the processing chamber.

11. The method of claim 1, wherein the densifying gas is a third gas different from the first reactive gas and the second reactive gas, and the film is exposed to radicals of the third gas, the radicals generated by passing the third gas across a thermal element.

12. The method of claim 1, wherein the film is densified after each exposure to the first reactive gas and the second reactive gas.

13. The method of claim 1, wherein the film is densified after forming a film having a thickness in the range of about 1 Å to about 50 Å.

14. The method of claim 1, wherein exposure to the first reactive gas and the second reactive gas occur substantially simultaneously at different regions of the substrate, so that there is substantially no mixing of the first reactive gas and the second reactive gas.

15. A method of forming a densified film comprising one or more of silicon nitride, silicon carbide or silicon carbonitride, the method comprising:
sequentially exposing the substrate to a first reactive gas comprising silicon and a second reactive gas comprising an agent to form a film on a surface of the substrate, the film being formed at a temperature less than about 500° C. and comprising one or more of silicon nitride, silicon carbide and silicon carbonitride; and
exposing the film to one or more of a plasma of a third gas or radicals of a third gas formed by passing the third gas across a thermal element to form a densified film, the third gas selected from the group consisting of Ar, N₂, H₂, He, NH₃ and mixtures thereof.

16. A method of forming a film on a substrate in a processing chamber, the method comprising:
sequentially exposing the substrate to a first reactive gas comprising dichlorosilane or hexachlorodisilane and a second reactive gas comprising ammonia to form a film; and
densifying the film with a densifying gas comprising one or more of a plasma and radicals to form a densified film and/or exposing the film to heat from a hot wire,
wherein the film is formed at a temperature less than about 500° C.

17. The method of claim 16, wherein the densifying gas comprises one or more of a plasma and radicals to form the densified film.

18. The method of claim 17, wherein the plasma comprises Ar and N₂.

19. The method of claim 18, wherein the densifying gas contains N* radicals.

20. The method of claim 16, wherein exposing the densifying gas to heat from a hot wire produces N* and/or NH* radicals.
